(19) United States
(12) Patent Application Publication
(10) Pub. No.: US 2021/0288257 A1
(43) Pub. Date: Sep. 16, 2021

(54) ORGANIC LIGHT-EMITTING DEVICE

(71) Applicant: Shenzhen China Star Optoelectronics Semiconductor Display Technology Co., Ltd., Shenzhen (CN)

(72) Inventor: Shuren ZHANG, Shenzhen (CN)

(73) Assignee: Shenzhen China Star Optoelectronics Semiconductor Display Technology Co., Ltd., Shenzhen (CN)

(21) Appl. No.: 16/625,810

(22) PCT Filed: Nov. 27, 2019
(86) PCT No.: PCT/CN2019/121263

§ 371 Date: Dec. 23, 2019

(30) Foreign Application Priority Data
Nov. 14, 2019 (CN) 201911115446.8

(51) Int. Cl. H01L 51/00

(52) U.S. Cl. CPC H01L 51/0039; H01L 51/502; H01L 51/0036; H01L 51/0035

(57) ABSTRACT

The present invention relates to an organic light-emitting device, comprising: a light-emitting layer, which is a quantum dot composite film, wherein the quantum dot composite film comprises a conductive polymer, a quantum dot, and a coordination group connected to the conductive polymer, and the coordination group is connected to the quantum dot.

### BACKGROUND OF INVENTION

The present application claims priority to Chinese patent application no. 201911115446.8 submitted to Chinese Patent Office on Nov. 14, 2019, entitled “organic light-emitting device”, the entire contents of which are incorporated herein by reference.

### Field of Invention

The present invention relates to a field of display technology, and in particular, to an organic light-emitting device.

### Description of Prior Art

Organic light-emitting display devices (OLED) are also called organic electric laser display devices or organic light-emitting semiconductors. A working principle of OLED is that when an electric power is supplied with an appropriate voltage, positive holes and cathode charges will be combined in a light-emitting layer, and under an action of Coulomb force, they will recombine to form excitons in an excited state (an electron-hole pair). Since this excited state is unstable in the ordinary environment, the excitons in the excited state are recombined and transfer energy to the light-emitting material, so that the light-emitting material transits from a ground state energy level to the excited state, and energy of the excited state is subjected to a radiation relaxation process to generate photons, releasing light energy to generate light, wherein RGB three primary colors of red, green, and blue are generated according to different formulas to constitute basic colors.

The OLED has advantages of low voltage demand, high power saving efficiency, fast response times, light weight, thin thickness, simple structure, low cost, wide viewing angles, almost infinitely high contrast, low power consumption, extremely high response speeds, etc., and has become one of the most important display technologies today.

In order to ensure that quantum dots can be stably dispersed in a solution, long chain alkane derivatives such as oleic acid or octadecylamine are usually used as organic ligands to coordinate with surfaces of the quantum dots. However, alkyl chains are usually insulative, so conductivity of the quantum dots after forming a film is poor. Thin films prepared by blending conjugated polymers and the quantum dots can significantly increase carrier mobility of a quantum dot layer and have a good film-forming property, but the polymer and the quantum dots will undergo phase separation, which impacts light-emitting stability of the device. Therefore, there is a need to develop a new type of organic light-emitting device to solve the above problems.

### SUMMARY OF INVENTION

An object of the present invention is to provide an organic light-emitting device, which can solve the problems of poor conductivity of a quantum dot film, separation of polymers and quantum dots, and the like in the existing organic light-emitting device.

In order to solve the above problems, an embodiment of the present invention provides an organic light-emitting device, including:

a light-emitting layer, which is a quantum dot composite film, wherein the quantum dot composite film includes a conductive polymer, a quantum dot, and a coordination group connected to the conductive polymer, and the coordination group is connected to the quantum dot.

Further, the conductive polymer has a side chain, and the coordination group is located on the side chain.

Further, the conductive polymer includes at least one of a PFN-based polymer, a triarylamine-based polymer, a polyfluorene-based polymer, and a polythiophene.

Further, the PFN-based polymer includes at least one of PFN-FP and PFN,

wherein the PFN-FP has a chemical structural formula as follows:

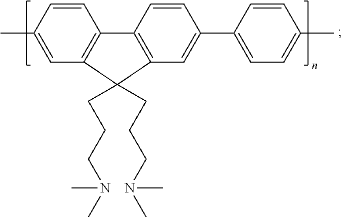

and

the PFN has a chemical structural formula as follows:

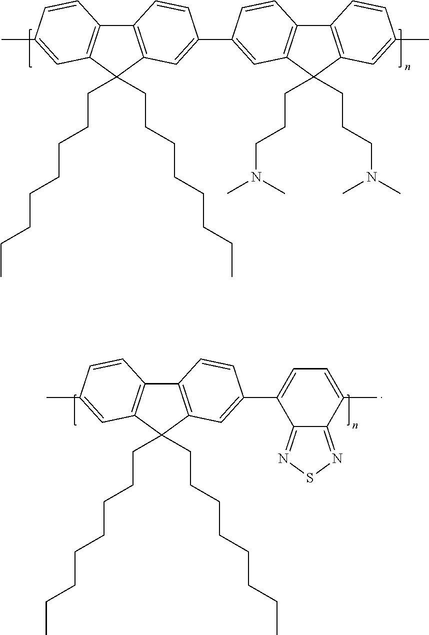

Further, the triarylamine-based polymer includes at least one of poly-TPD and TFB,

wherein the poly-TPD has a chemical structural formula as follows:

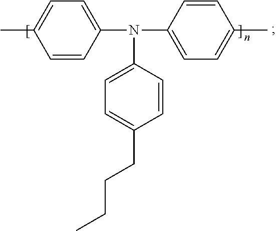

and

the TFB has a chemical structural formula as follows:

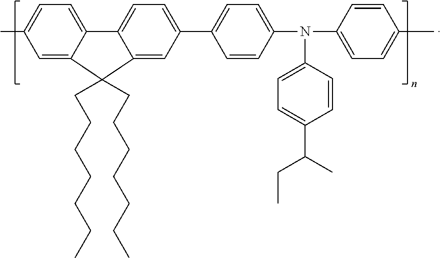

Further, the polyfluorene-based polymer includes at least one of F8T2, PFO, and F8BT,

wherein the F8T2 has a chemical structural formula as follows:

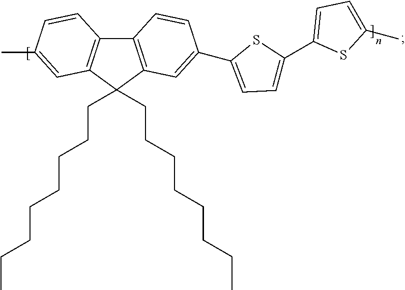

the PFO has a chemical structural formula as follows:

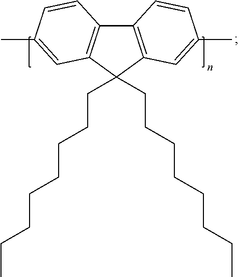

and

the F8BT has a chemical structural formula as follows:

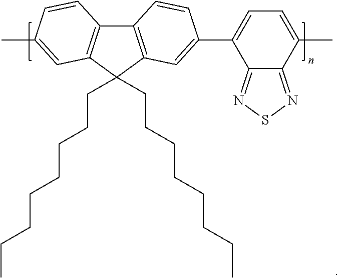

Further, the quantum dot includes one or more of a core-shell structure quantum dot and a perovskite quantum dot.

Further, the core-shell structure quantum dot includes one or more of CdSe, CdS, and InP.

Further, the coordination group includes one or more of —COOH, —OH, —NH₂, and —SH.

Further, the organic light-emitting device further includes:

a substrate;

an anode disposed on the substrate;

a hole injection layer disposed on the anode;

a hole transport layer disposed on the hole injection layer;

a light-emitting layer disposed on the hole transport layer;

an electron transport layer disposed on the light-emitting layer;

an electron injection layer disposed on the electron transport layer; and

a cathode disposed on the electron injection layer.

The invention relates to an organic light-emitting device, which includes: a light-emitting layer, which is a quantum dot composite film, wherein the quantum dot composite film includes a conductive polymer, a quantum dot, and a coordination group connected to the conductive polymer, and the coordination group is connected to the quantum dot. By introducing a coordination group on a side chain of the conductive polymer and then subjecting the coordination group to a ligand exchange with the quantum dot, the conductive polymer will be connected to the quantum dot by a coordination bond, such that the light-emitting layer prepared thereby not only has a good film-forming property, but also has a significant improvement in carrier mobility. In addition, due to the presence of the coordination bond, separation between the conductive polymer and the quantum dot can be effectively suppressed, and the quantum dots are uniformly dispersed in the light-emitting layer to improve performance and light-emitting stability of the organic light-emitting device.

### BRIEF DESCRIPTION OF DRAWINGS

FIG. 1 is a schematic structural diagram of an organic light-emitting device according to the present invention.

In order to more clearly illustrate the embodiments or the technical solutions of the existing art, the drawings illustrating the embodiments or the existing art will be briefly described below. Obviously, the drawings in the following description merely illustrate some embodiments of the present invention. Other drawings may also be obtained by those skilled in the art according to these figures without paying creative work.

Elements in the drawings are designated by reference numerals listed below.
100. organic light-emitting device
1. substrate
2. anode
3. hole injection layer
4. hole transport layer
5. light-emitting layer
6. electronic transport layer
7. electron injection layer
8. cathode

### DETAILED DESCRIPTION OF PREFERRED EMBODIMENTS

The preferred embodiments of the present invention are described in detail below with reference to the accompanying drawings, in which FIG. Those skilled in the art will more readily understand how to implement the invention. The present invention may, however, be embodied in many different forms and embodiments, and the scope of the invention is not limited to the embodiments described herein.

The following description of the various embodiments is provided to illustrate the specific embodiments of the invention. The spatially relative directional terms mentioned in the present invention, such as “upper”, “lower”, “before”, “after”, “left”, “right”, “inside”, “outside”, “side”, etc. and the like, may be used herein for ease of description to describe one element or feature's relationship to another element(s) or feature(s) as illustrated in the figures which are merely references.

In the drawings, the spatially relative terms are intended to encompass different orientations in addition to the orientation as depicted in the figures. Moreover, the size and thickness of each component shown in the drawings are arbitrarily shown for ease of understanding and description, and the invention does not limit the size and thickness of each component.

When a component is described as “on” another component, the components are formed in direct contact, and may also include embodiments in which additional features may be formed interposing the first and second features, such that the first and second features may not be in direct contact. When a component is described as “installed to” or “connected to” another component, it can be understood that a component is “directly installed” or “directly connected” to another component, or a component is “installed to” or “connected with” another component through an intermediate component.

### EXAMPLE 1

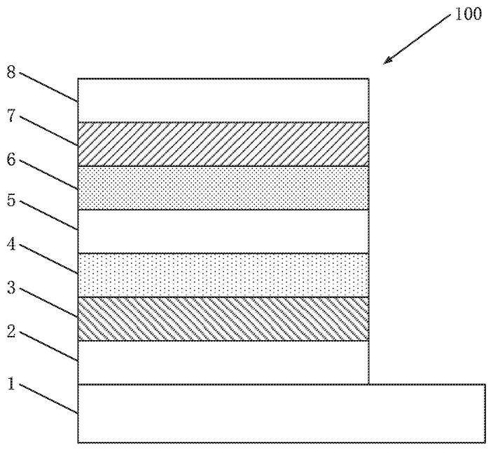

As shown in FIG. 1, an organic light-emitting device 100 includes: a substrate 1, an anode 2, a hole injection layer 3, a hole transport layer 4, a light-emitting layer 5, an electron transport layer 6, an electron injection layer 7, and a cathode 8.

As shown in FIG. 1, the anode 2 is disposed on the substrate 1, and the hole injection layer 3 is disposed on the anode 2.

As shown in FIG. 1, the hole-transport layer 4 is disposed on the hole-injection layer 3, wherein the hole-transport layer 4 controls transport of holes, and further controls recombination of the holes with electrons in the light-emitting layer 5, thereby improving light-emitting efficiency.

As shown in FIG. 1, the light-emitting layer 5 is disposed on the hole transport layer 4. The light-emitting layer 5 is a quantum dot composite film, and the quantum dot composite film includes a conductive polymer, a quantum dot, and a coordination group connected to the conductive polymer, and the coordination group is connected to the quantum dot.

The conductive polymer has a side chain, and the coordination group is located on the side chain.

The conductive polymer includes at least one of a PFN-based polymer, a triarylamine-based polymer, a polyfluorene-based polymer, and a polythiophene.

The PFN-based polymer includes at least one of PFN-FP and PFN, wherein

the PFN-FP has a chemical structural formula as follows:

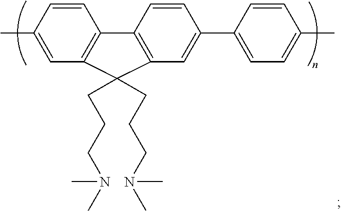

and

the PFN has a chemical structural formula as follows:

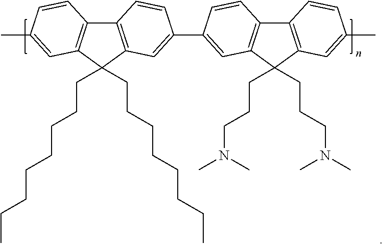

The triarylamine-based polymer includes at least one of poly-TPD and TFB,

wherein the poly-TPD has a chemical structural formula as follows:

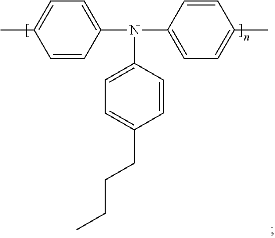

and

the TFB has a chemical structural formula as follows:

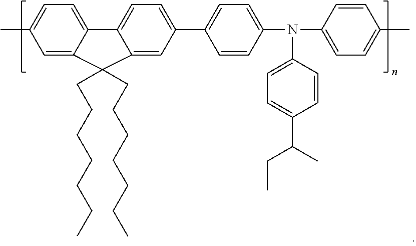

The polyfluorene-based polymer includes at least one of F8T2, PFO, and F8BT,

wherein the F8T2 has a chemical structural formula as follows:

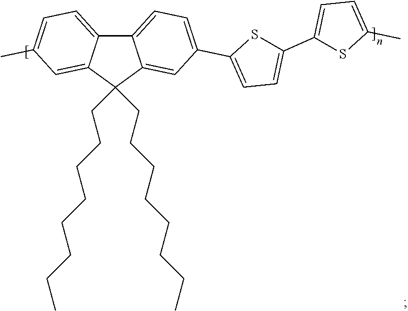

the PFO has a chemical structural formula as follows:

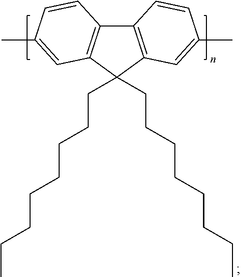

and

the F8BT has a chemical structural formula as follows:

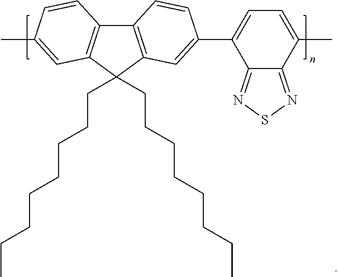

The quantum dot includes one or more of a core-shell structure quantum dot and a perovskite quantum dot.

The core-shell structure quantum dot includes one or more of CdSe, CdS, and InP.

The coordination group includes one or more of —COOH, —OH, —NH₂, and —SH.

By introducing a coordination group on a side chain of the conductive polymer and then subjecting the coordination group to a ligand exchange with the quantum dot, the conductive polymer will be connected to the quantum dot by a coordination bond, such that the light-emitting layer 5 prepared thereby not only has a good film-forming property, but also has a significant improvement in carrier mobility.

In addition, due to the presence of the coordination bond, separation between the conductive polymer and the quantum dot can be effectively suppressed, and the quantum dots are uniformly dispersed in the light-emitting layer 5 to improve performance and light-emitting stability of the organic light-emitting device 100.

Specifically, the quantum dot and the conductive polymer can be dissolved in chloroform in a mass ratio which is optimized to have a range of 1:1-1:200, followed by stirring overnight at room temperature, and then methanol is added to the chloroform for precipitation, followed by centrifugally separating the quantum dot composite, such that a quantum dot composite film can be prepared by inkjet printing or spin coating. Specifically, the quantum dot composite is dissolved in xylene and then spin-coated, and the quantum dot composite film is obtained after annealing. Alternatively, the quantum dot composite film can be obtained by formulating the quantum dot composite into ink, and the ink is dropped to predetermined positions by printing, followed by vacuum drying, and then annealing.

As shown in FIG. 1, the electron transport layer 6 is disposed on the light-emitting layer 5. The electron transport layer 6 controls the transport of electrons, and further controls the recombination of electrons with holes in the light-emitting layer 5, thereby improving light-emitting efficiency.

As shown in FIG. 1, the electron injection layer 7 is disposed on the electron transport layer 6, and the cathode 8 is disposed on the electron injection layer 7.

The organic light-emitting device provided by the present invention has been described in detail above. It should be understood that the exemplary embodiments described herein should only be considered as descriptive, to help understand the method of the present invention and its core ideas, and not to limit the present invention. Descriptions of features or aspects in each exemplary embodiment should typically be considered as applicable to similar features or aspects in other exemplary embodiments. Although the present invention has been described with reference to exemplary embodiments, various changes and modifications may be suggested to those skilled in the art. The present invention is intended to cover these changes and modifications within the scope of the appended claims. Any modification, equivalent replacement, and improvement made within the spirit and principle of the present invention shall be included in the protection scope of the present invention.

What is claimed is:

1. An organic light-emitting device, comprising:
a light-emitting layer, which is a quantum dot composite film, wherein the quantum dot composite film comprises a conductive polymer, a quantum dot, and a coordination group connected to the conductive polymer, and the coordination group is connected to the quantum dot.

2. The organic light-emitting device according to claim 1, wherein the conductive polymer has a side chain, and the coordination group is located on the side chain.

3. The organic light-emitting device according to claim 1, wherein the conductive polymer comprises at least one of a PFN-based polymer, a triarylamine-based polymer, a polyfluorene-based polymer, and a polythiophene.

4. The organic light-emitting device according to claim 3, wherein the PFN-based polymer comprises at least one of PFN-FP and PFN,
wherein the PFN-FP has a chemical structural formula as follows: 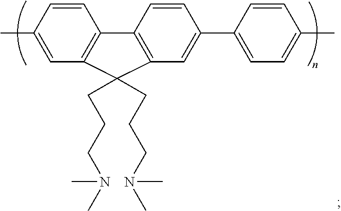
and
the PFN has a chemical structural formula as follows:

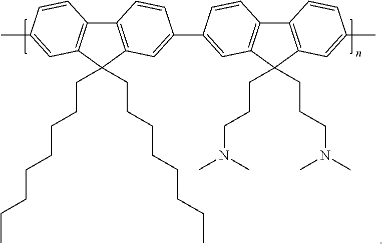

5. The organic light-emitting device according to claim 3, wherein the triarylamine-based polymer comprises at least one of poly-TPD and TFB,
wherein the poly-TPD has a chemical structural formula as follows: 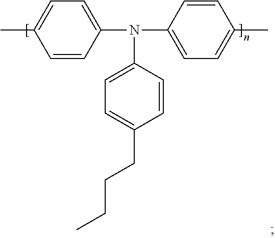
and
the TFB has a chemical structural formula as follows:

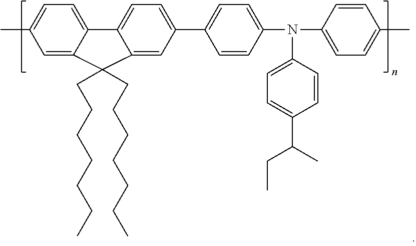

6. The organic light-emitting device according to claim 3, wherein the polyfluorene-based polymer comprises at least one of F8T2, PFO, and F8BT, wherein the F8T2 has a chemical structural formula as follows: 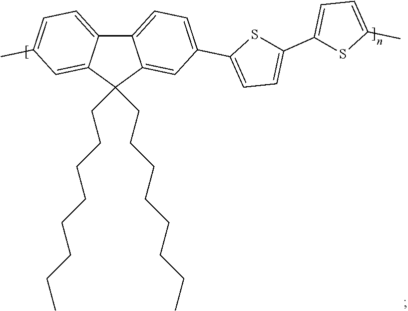
the PFO has a chemical structural formula as follows: 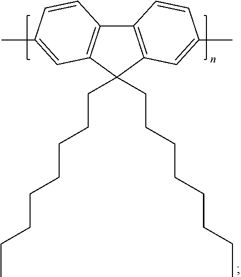
and
the F8BT has a chemical structural formula as follows:

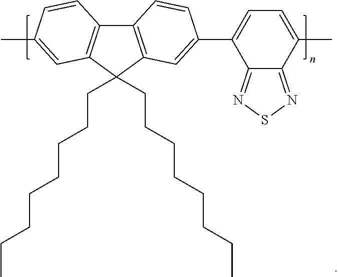

7. The organic light-emitting device according to claim 1, wherein the quantum dot comprises one or more of a core-shell structure quantum dot and a perovskite quantum dot.

8. The organic light-emitting device according to claim 7, wherein the core-shell structure quantum dot comprises one or more of CdSe, CdS, and InP.

9. The organic light-emitting device according to claim 1, wherein the coordination group comprises one or more of —COOH, —OH, —NH₂, and —SH.

10. The organic light-emitting device according to claim 1, further comprising:
a substrate;
an anode disposed on the substrate;
a hole injection layer disposed on the anode;
a hole transport layer disposed on the hole injection layer;
a light-emitting layer disposed on the hole transport layer;
an electron transport layer disposed on the light-emitting layer;
an electron injection layer disposed on the electron transport layer; and
a cathode disposed on the electron injection layer.
